(19) United States
(12) Patent Application Publication
(10) Pub. No.: US 2002/0175329 A1
(43) Pub. Date: Nov. 28, 2002

(54) Semiconductor apparatus and method of making same

(76) Inventor: Tomoyuki Hirano, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 10/144,232

(22) Filed: May 10, 2002

(30) Foreign Application Priority Data
May 10, 2001 (JP) P2001-139792

(51) Int. Cl. H01L 27/108

(52) U.S. Cl. 257/68

(57) ABSTRACT

A semiconductor apparatus which allows for an increase in the surface area of a lower electrode constituting a concave capacitor, and is capable of increasing the capacitance of an MIM structure, and a method of making such a semiconductor apparatus are provided. On a sidewall section of an amorphous silicon, an HSG silicon is selectively formed. A lower electrode is formed by the AL-CVD method in a thickness of 10 nm so as to cover the HSG silicon. Subsequently, a dielectric film is formed such that it covers the lower electrode and a cylinder core layer. Finally, a cell plate which is to constitute an upper electrode is formed on the dielectric film, and a capacitor is thereby completed.

### CROSS REFERENCE TO RELATED APPLICATIONS

The present document is based on Japanese Priority Document JP 2001-139792, filed in the Japanese Patent Office on May 10, 2001, the entire contents of which are incorporated herein by reference to the extent permitted by law.

### BACKGROUND OF THE INVENTION

1. Field of the Invention

The present invention relates to a semiconductor apparatus having a capacitor, and a method of making such a semiconductor. Specifically, the present invention relates to a semiconductor apparatus having a capacitor such as a DRAM (Dynamic Random Access Memory).

2. Description of the Related Art

In semiconductor apparatuses, and especially in semiconductor memory apparatuses, capacitors are used as a means for retaining information. For example, DRAM's have a field effect transistor comprising a metal-oxide-semiconductor stack (MOSFET, or metal-oxide-semiconductor field effect transistor) for switching purposes and a memory cell structure comprising a memory capacitor, and, in recent years, DRAM's are becoming increasingly refined, downsized, integrated, and capable of mass storage. In order for a capacitor in an integrated semiconductor apparatus to sufficiently perform memory cell functions, a certain level of capacitance must be secured, regardless of the DRAM's generation. This is because in order to increase the reliability of data by eliminating soft errors caused by alpha rays, and by securing an ample margin against noise, a storage volume of the memory capacitor must be held at a stable value such as 20 to 30 fF.

In today's IC circuit apparatus, however, the area occupied by a capacitor in each unit memory cell is decreasing as semiconductor apparatuses become integrated to a higher order. This signifies that the capacitance of the capacitor is decreasing as well. Therefore, in highly integrated semiconductor apparatuses, in order to increase the capacitance of the capacitors mounted thereon, methods using a ferroelectric film having a high dielectric constant, and methods where the surface areas of capacitor electrodes are increased have been proposed.

As an example of a method where the surface area of electrodes is increased, a method involving hemispherical grained films (HSG film) has already been proposed (for example, in laid-open Japanese Patent Application 8-306646). In this method, by directing a flow of silane (SiH₄) gas onto an amorphous silicon (Si) film containing impurities, Si grain nuclei are formed on the surface of the amorphous Si film. Subsequently, heat-treatment is performed, and Si atoms on the surface of the amorphous Si film migrate towards the Si grain nuclei. As a result, hemispherical grained (HSG) silicon is formed on the surface of the amorphous Si film.

Currently, in order to increase the surface area of electrodes using such an HSG film, using capacitors with an MIS (Metal-Insulator-Semiconductor) structure is mainstream, however, with this structure, because electrical resistance is high, it is becoming difficult to accommodate high speed operation. Thus, capacitors with an MIM (Metal-Insulator-Metal) structure using metal (such as TiN, WN, Ru, etc.) for a lower electrode are being proposed for purposes of lowering electrical resistance.

Also, in the field of capacitors with a three-dimensional structure referred to as stack type capacitors, cylindrical structures are mainstream. However, as the area occupied by each unit cell decreases, and storage nodes between adjacent cells are brought closer to one another beyond the limits of lithography, the thickness of the film of the wall towards the cylinder starts to become as thin as is attainable. Thus, in order to configure a three-dimensionally structured capacitor, it had to be a concave capacitor which uses only the inner wall of the cylinder.

### SUMMARY OF THE INVENTION

However, in a concave capacitor with an MIM structure, unlike a conventional capacitor with an MIS structure using an HSG film, a lower electrode configured as a metal electrode is formed with a flat surface. As a result, making the surface area of a concave capacitor sufficiently large in order to obtain a large storage capacitor with a conventional MIM structure is difficult, inevitably resulting in an increase in capacitor height, or a shortage in capacitance.

In view of such problems described above, it is an aspect of the present invention to provide a semiconductor apparatus and/or a method of making same, which are capable of increasing the capacitance of an MIM structure by increasing the surface area of a lower electrode constituting a concave capacitor.

In order to achieve the aspect mentioned above, a semiconductor apparatus having a capacitor is provided. This semiconductor apparatus includes a first amorphous semiconductor film formed so as to cover a hole core pattern formed on a semiconductor substrate, a second amorphous semiconductor film formed on the first amorphous semiconductor film such that convex sections are formed, a lower electrode formed such that it covers the second amorphous semiconductor film and a dielectric film interposed between an upper electrode formed on the lower electrode.

An apparatus configured as described above is capable of increasing the surface area of the lower electrode, and of increasing the capacitance of the MIM structure.

As described above, in the method of manufacturing a semiconductor apparatus according to the present invention, the second amorphous semiconductor film (HSG silicon) is formed on the first amorphous semiconductor film such that convex sections are formed. This second amorphous semiconductor film thus formed enables the formation of a surface having concave and convex sections on a metal film or metal mixture film constituting the lower electrode. Thus, the surface area of the lower electrode in a concave capacitor having an MIM structure can be increased drastically. This makes it possible to manufacture a semiconductor apparatus having a low-resistance and large-storage capacitor.

### BRIEF DESCRIPTION OF THE DRAWINGS

The above and other aspects, features and advantages of the present invention will become more apparent to those skilled in the art from the following description of the presently preferred exemplary embodiments of the invention taken in conjunction with the accompanying drawings, in which:

FIGS. 1A through 1C are cross sectional views showing manufacturing processes for a DRAM having a concave storage node electrode;

FIGS. 2A and 2B are cross sectional views showing manufacturing processes for a DRAM following FIG. 1C;

FIGS. 3A and 3B are cross-sectional views of manufacturing processes for a DRAM following FIG. 2B;

FIG. 3C is an enlarged view of section H indicated in FIG. 3B;

FIG. 4A is a cross sectional view showing a manufacturing process for a DRAM following FIG. 3B;

FIG. 4B is an enlarged view of section J indicated in FIG. 4A;

FIG. 5A is a cross sectional view showing a manufacturing process for a DRAM following FIG. 4A;

FIG. 5B is an enlarged view of section L indicated in FIG. 5A;

FIG. 6A is a cross sectional view showing a semiconductor apparatus according to the first embodiment of the present invention;

FIG. 6B is an enlarged view of section N indicated in FIG. 6A; and

FIG. 7 is a cross sectional view of a semiconductor apparatus according to the third embodiment of the present invention;

### DESCRIPTION OF THE PREFERRED EMBODIMENTS

Below, preferred embodiments of the present invention are described in detail with reference to the accompanying drawings. In all of the figures for the preferred embodiments described below, the same, or corresponding sections and elements are identified with the same reference numerals.

<First Embodiment>

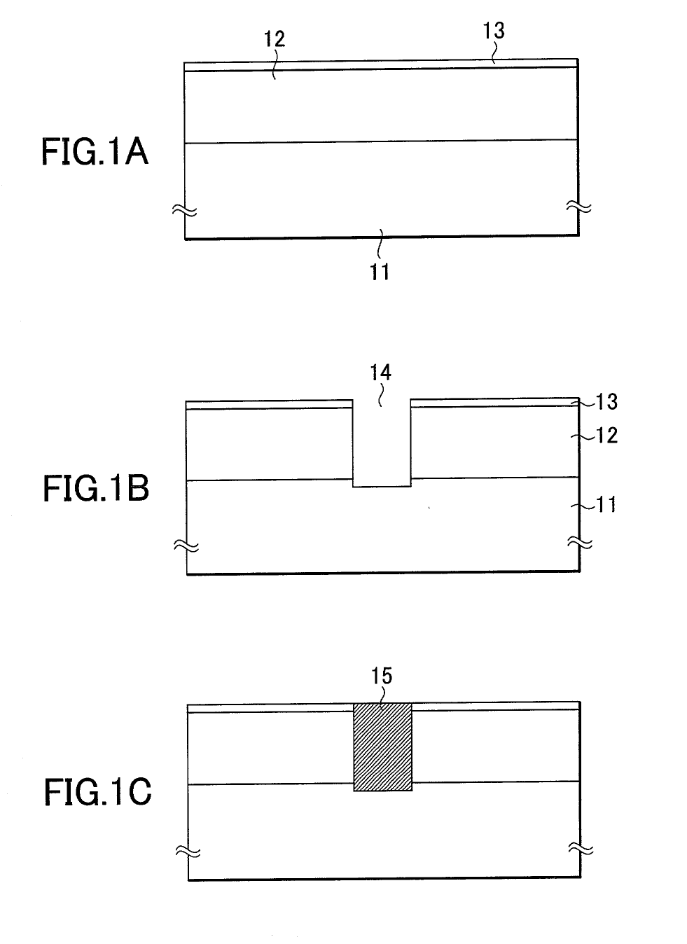

FIGS. 1A through 6B indicate a method of manufacturing a semiconductor apparatus according to a first embodiment of the present invention.

FIGS. 1A through 1C are cross sectional views showing manufacturing processes for a DRAM having a concave storage node electrode. In a DRAM, one transistor and one memory capacitor constitute one memory cell, but in these figures, the transistor of the semiconductor substrate is not shown.

In the process shown in FIG. 1A, an interlayer insulation film 12 is formed on the entire surface of a semiconductor substrate 11. Subsequently, a stopper layer 13 is formed on the entire surface of the interlayer insulation film 12. The stopper layer 13 is a layer which functions as a stopper when, during the subsequent processes, a cylinder core layer is removed, and is, for example, a silicon nitride film of a thickness of 100 nm formed using the CVD (Chemical Vapor Deposition) method.

In the process illustrated in FIG. 1B, a contact hole 14 which reaches the semiconductor substrate 11 is formed by performing anisotropic etching on the stopper layer 13 as well as the interlayer insulation film 12 using a resist pattern not shown in the figure as a mask.

In the process illustrated in FIG. 1C, a conductive film which is to become a silicon plug 15 is deposited inside the contact hole 14. This conductive film is, for example, amorphous silicon containing phosphorus (P), or is polysilicon, and after being deposited inside the contact hole 14, it is planarized by the chemical-mechanical polishing (CMP) method, and becomes the silicon plug 15 which connects the transistor and the lower electrode of the memory capacitor of the semiconductor substrate 11.

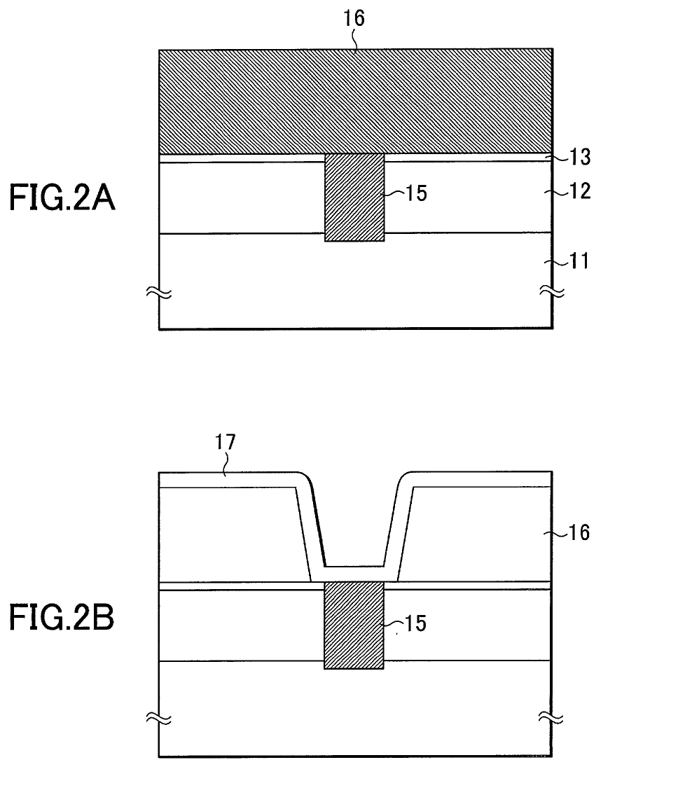

FIGS. 2A and 2B are cross sectional views showing manufacturing processes for a DRAM following the process of FIG. 1C.

In the process shown in FIG. 2A, a cylinder core layer 16 comprising a silicon oxide type material is formed in a film thickness of 1000 nm or thereabout. As a silicon oxide type material for the cylinder core layer 16, BPSG (Boro Phospho Silicate Glass), for example, may be suitable.

In the process shown in FIG. 2B, a hole core pattern is formed on the cylinder core layer 16 by performing etching using a resist pattern (not shown) as a mask. As a result of this patterning, the upper surface of the silicon plug 15 becomes exposed. Then, as a first amorphous semiconductor film, an amorphous silicon layer 17 is formed on the cylinder core layer 16 such that the hole core pattern is covered.

In this example, the amorphous silicon layer 17 will be defined as phosphorus-doped polysilicon having a phosphorus concentration of 1.0× E20 atoms/cm³. When the phosphorus concentration of the phosphorus-doped polysilicon is too high, it causes crystal deformation later during the formation of an HSG film. Therefore, in order to perform HSG [symbol] of the amorphous silicon effectively, it is preferable that the phosphorus concentration of the amorphous silicon layer 17 be set below 2.0× E20 atoms/cm³. Further, while the film thickness of the amorphous silicon layer 17 is dictated by the inner radius of the holes of the core pattern, it is preferable that it be set within a range of 5 nm to 100 nm.

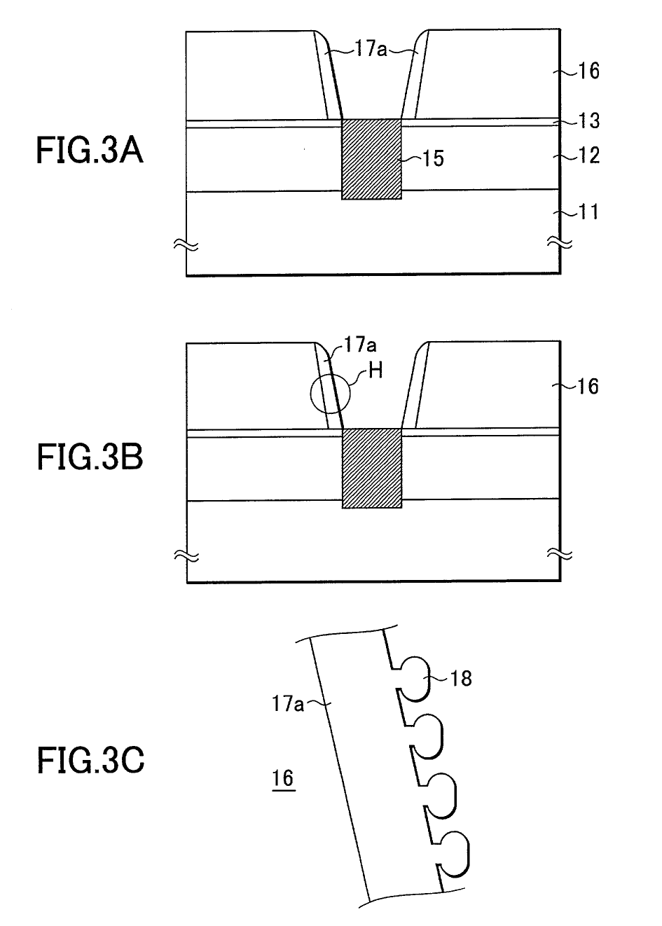

FIGS. 3A and 3B are cross sectional views showing manufacturing processes for a DRAM following the process of FIG. 2B. FIG. 3C is an enlarged view of the encircled section H shown in FIG. 3B.

In the process shown in FIG. 3A, the amorphous silicon layer 17 is partially removed through isotropic etching. An upper surface of the cylinder core 16 and the silicon plug 15 inside the holes in the core pattern are thereby exposed. As a result of this etching process, only a part of the amorphous silicon layer 17, which constitutes a sidewall section 17a of the cylinder core 16, remains. This etching is performed with the RIE (reactive ion etching) method, which uses, for example, C₁₂, SF₆ or the like as an etching gas.

In the process shown in FIG. 3B, by feeding silane (SiH₄) gas or disilane (Si₂H₆) gas inside a reaction chamber at a predefined flow rate, Si grain nuclei are selectively formed on the sidewall section 17a of the amorphous silicon layer 17. With respect to the reaction chamber, the internal temperature, the silane gas flow rate and the duration of gas infusion are set at 550° C.˜570° C., 20˜100 sccm and 10˜30 mins, respectively. Then, the feeding of gas to the reaction chamber is stopped, and annealing under ultra-high vacuum or inert gas is performed for 5˜60 mins. Thus, as shown in FIG. 3C, HSG silicon 18 as a second amorphous semiconductor layer is selectively formed on the sidewall section 17a of the amorphous silicon layer 17.

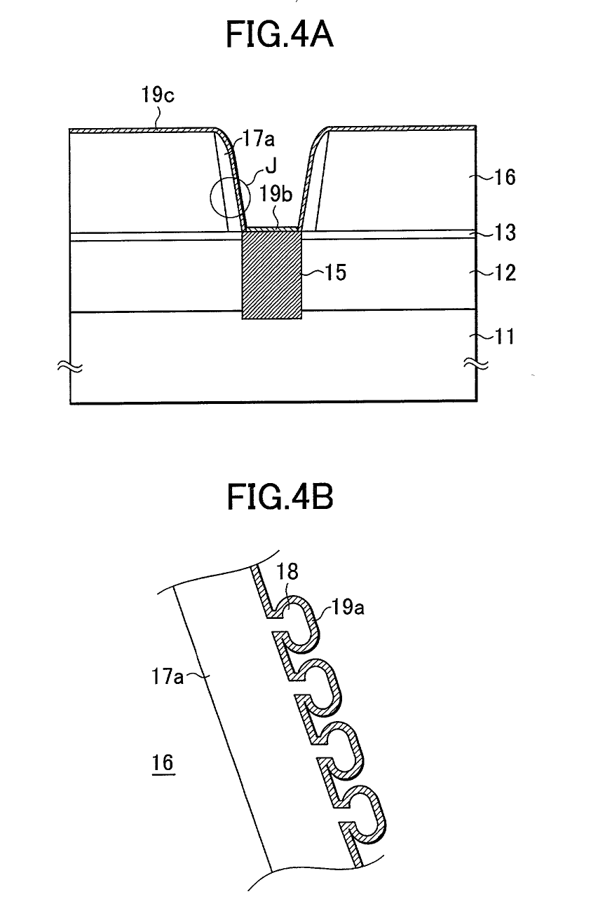

FIG. 4A is a cross sectional view showing a manufacturing process for a DRAM following the process of FIG. 3B. FIG. 4B is an enlarged view of the encircled section J shown in FIG. 4A.

During this process, first, a contact electrode 19b for a lower electrode 19a and the silicon plug 15 is formed by a metal film 19. It is preferable that this contact electrode 19b be formed with, for example, titanium (Ti) in a thickness of 3 nm using the sputter method. The contact electrode 19b may also be formed with a metallic compound film, and it may be formed using the CVD method as well.

Next, a metal film such as tungsten and the like, or a metallic compound film such as titanium nitride (TiN) and the like, which is to become the lower electrode 19a is formed. For the lower electrode 19a, a metal containing conductive film containing one of titanium nitride (TiN), tantalum nitride (TaN), ruthenium (Ru), ruthenium oxide (RuO₂) or platinum (Pt) may also be used.

The lower electrode 19a is formed by, for example, the AL-CVD (Atomic Layer Chemical Vapor Deposition) method in a thickness of 10 nm and such that it covers the foundation of HSG silicon 18 forming convex sections. If the film thickness of this lower electrode 19a is too thick, the spaces between the convex sections of the HSG silicon 18 become filled, and the increase in storage capacity is thereby reduced. When the film thickness is too thin, on the other hand, the resistance of the electrode increases due to a thin film effect. Thus, it is preferable that the film thickness of the lower electrode 19a be set between 3 nm˜30 nm.

A metal film 19c deposited on the upper surface of the cylinder core layer 16 is later removed by, for example, a CMP method. Thus, the lower electrode 19a and the contact electrode 19b are formed as node electrodes only inside each hole of the core pattern.

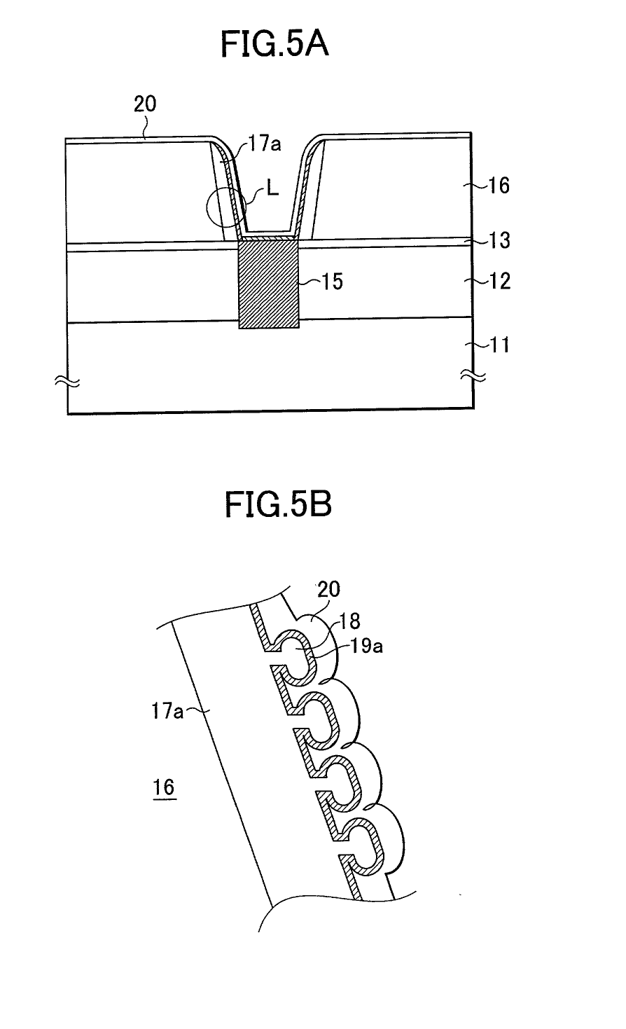

FIG. 5A is a cross sectional view showing a manufacturing process for a DRAM following the process of FIG. 4A. FIG. 5B is an enlarged view showing section L encircled in FIG. 5A.

In this process, a dielectric film 20 as a capacitor insulation film is formed so as to cover both the lower electrode 19a and the cylinder core 16. This dielectric film 20 is formed by the AL-CVD method as a Ta₂O₅ film of a thickness of 6 nm, for example.

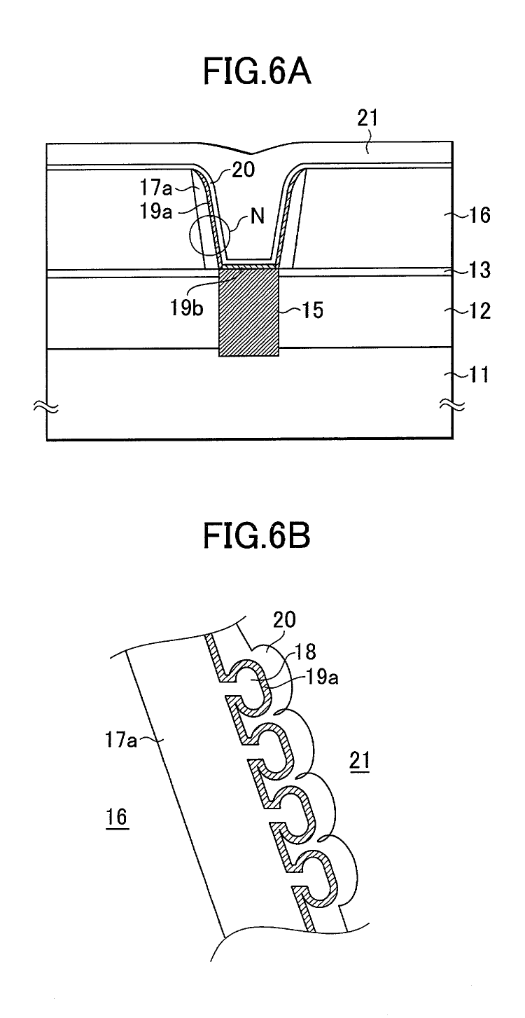

FIG. 6A is a cross sectional view showing a semiconductor apparatus according to the first embodiment of the present invention. FIG. 6B is an enlarged view showing section N encircled in FIG. 6A.

In this semiconductor apparatus, the capacitor is completed by forming an upper electrode 21, which is to become a cell plate, on the dielectric film 20. This upper electrode 21 is, for example, TiN deposited by the CVD method in a thickness of 30 nm.

<Second Embodiment>

Next, a method of manufacturing a semiconductor apparatus according to a second embodiment of the present invention is described.

In the first embodiment described above, during the process explained with reference to FIG. 3A, the amorphous silicon film 17 is removed by isotropic etching, after which the HSG silicon 18 is formed. What differs in the second embodiment is that these steps are reversed and an HSG silicon 18 is formed first, subsequent to which isotropic etching is performed such that only a sidewall section 17a remains. All other processes are the same as those described for the first embodiment.

In other words, in the method of manufacturing a semiconductor apparatus according to the second embodiment, after the HSG silicon 18 is formed, as shown in FIG. 3C, on the entire surface of an amorphous silicon film 17 shown in FIG. 2B, the amorphous silicon film 17 is partially removed by isotropic etching in the process illustrated in FIG. 3A.

<Third Embodiment>

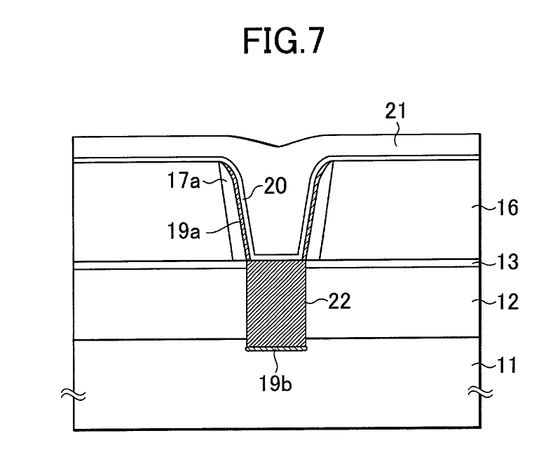

FIG. 7 is a cross sectional view showing a semiconductor apparatus according to a third embodiment of the present invention.

In the first embodiment, the silicon plug 15 was used inside the contact hole 14. However, metals or metallic compounds may also be used.

In FIG. 7, unlike the first embodiment shown in FIGS. 6A and 6B, a lower electrode 19a and a metal electrode 22 is connected directly, and a contact electrode 19b is formed on a lower surface of the metal electrode 22 which is connected with either a source area or a drain area of a semiconductor substrate 11. Therefore, the contact electrode 19b needs to be formed before the metal electrode 22 is formed.

Further, if a tungsten plug is formed as the metal electrode 22, a barrier layer of TiN or the like may be provided after the formation of the contact electrode 19b.

What is claimed is:

1. A semiconductor apparatus having a capacitor, comprising:
a first amorphous semiconductor film formed such that it covers a hole core pattern formed on a semiconductor substrate;
a second amorphous semiconductor film formed such that it forms convex sections on said first amorphous semiconductor film;
a lower electrode formed such that it covers said second amorphous semiconductor film; and
an upper electrode formed on said lower electrode with a dielectric film interposed between said upper electrode and said lower electrode.

2. The semiconductor apparatus according to claim 1, wherein said second amorphous semiconductor film is an amorphous silicon film having a hemispherical grained film of silicon on a surface thereof.

3. The semiconductor apparatus according to claim 1, wherein said lower electrode is a metal film or a metallic compound film having a thickness of 3 nm to 30 nm.

4. The semiconductor apparatus according to claim 3, wherein said metal film, or said metallic compound film having a metal containing conductive film containing one of titanium nitride (TiN), tungsten nitride (WN), tantalum nitride (TaN), ruthenium (Ru), ruthenium oxide (RuO₂), and platinum (Pt).

5. The semiconductor apparatus according to claim 1, wherein said capacitor is formed on said semiconductor substrate, and is connected to a semiconductor device in said semiconductor substrate by a silicon plug via an interlayer insulation film.

6. The semiconductor apparatus according to claim 1, wherein said capacitor is formed on said semiconductor substrate, and is connected to a semiconductor device in said semiconductor substrate by a metal plug or a metallic compound plug via an interlayer insulation film.

7. A method of making a semiconductor apparatus having a capacitor, comprising:
a first process wherein an amorphous silicon film is formed so as to cover a hole core pattern formed on a semiconductor substrate;
a second process wherein portions of said amorphous silicon film, except for portions along sidewalls of holes in said core pattern, are removed by isotropic etching;
a third process wherein a hemispherical grained film is developed on a surface of said amorphous silicon film left on said sidewalls; and
a fourth process wherein a metal film or a metallic compound film is formed as a lower electrode such that said lower electrode covers said hemispherical grained film.

8. A method of making a semiconductor apparatus having a capacitor, comprising:
a first process wherein an amorphous silicon film is formed so as to cover a hole core pattern formed on a semiconductor substrate;
a second process wherein a silicon hemispherical grained film is developed on a surface of said amorphous silicon film;
a third process wherein portions of said amorphous silicon film, except for portions formed on sidewalls of holes of said core pattern, are removed by isotropic etching; and
a fourth process wherein a metal film or a metallic compound film is formed as a lower electrode so as to cover said hemispherical grained film on said portion of said amorphous silicon film left on said sidewalls.

9. A method of making a semiconductor apparatus having a capacitor, comprising:
forming an amorphous silicon film so as to cover a hole core pattern formed on a semiconductor substrate;
developing a silicon hemispherical grained film on a surface of said amorphous silicon film;
removing portions of said amorphous silicon film, except for portions formed on sidewalls of holes of said core pattern, by isotropic etching; and
forming a metal film or a metallic compound film as a lower electrode so as to cover said hemispherical grained film on said portion of said amorphous silicon film left on said sidewalls.
